(19) United States
(12) Patent Application Publication
(10) Pub. No.: US 2012/0161791 A1
(43) Pub. Date: Jun. 28, 2012

(54) METHODS AND APPARATUS FOR DETERMINING INPUT OBJECTS ASSOCIATED WITH PROXIMITY EVENTS

(75) Inventor: Scott J. Shaw, Fremont, CA (US)

(73) Assignee: SYNAPTICS INCORPORATED, Santa Clara, CA (US)

(21) Appl. No.: 12/979,771

(22) Filed: Dec. 28, 2010

(51) Int. Cl. G01R 27/26

(52) U.S. Cl. 324/658

(57) ABSTRACT

A system determines whether proximity events at different positions are produced by the same input object or by different input objects. One or more hover states (or proximity events with “non-contact” signatures) occurring near the two positions are used in making this determination. The proximity events are found to be produced by different input objects, for example, when the hover state occurs at approximately the first position within a first duration after a first time, or at approximately the second position within a second duration before the second time.

### FIELD OF THE INVENTION

The present invention generally relates to electronic devices, and more specifically relates to sensor devices.

### BACKGROUND OF THE INVENTION

Input devices, including proximity sensor devices (also commonly called touchpads or touch sensor devices), are widely used in a variety of electronic systems. A proximity sensor device typically includes a sensing region, often demarked by a surface, in which the proximity sensor device determines the presence, location and/or motion of one or more input objects. Proximity sensor devices may be used to provide interfaces for the electronic system. For example, proximity sensor devices are often used as input devices for larger computing systems (such as opaque touchpads integrated in, or peripheral to, notebook or desktop computers). Proximity sensor devices are also often used in smaller computing systems (such as touch screens integrated in cellular phones).

It is common for users to tap or “drum” their fingers or other input objects on the surface of a touch sensor device. In such cases, it can be difficult to determine whether the corresponding proximity events are produced by the same input object (e.g., an index finger moving quickly), or by two different input objects (e.g., the index finger and a ring finger drumming on the surface). This ambiguity can lead to misinterpretation of user intent.

Accordingly, there is a need for improved systems and methods for determining whether proximity events are produced by the same input object or by different input objects. Other desirable features and characteristics will become apparent from the subsequent detailed description and the appended claims, taken in conjunction with the accompanying drawings and the foregoing technical field and background.

### BRIEF SUMMARY OF THE INVENTION

A touch sensor method in accordance with one embodiment includes: detecting a first proximity event at a first position at a first time, and a second proximity event at a second position at a second time, wherein the first and second proximity events have a contact signature. The method further includes determining that the first proximity event and the second proximity event are caused by different input objects in response to detecting a third proximity event either (a) near the first position within a first duration after the first time, or (b) near the second position within a second duration before the second time, wherein the third proximity event has a non-contact signature.

A processing system for an input device in accordance with another embodiment includes a sensing module configured to acquire a set of sensor values using at least one sensing element of the input device, the set of sensor values including information indicative of a first object position occurring at a first time, a second object position occurring at a second time, and a hover state near the first object position within a first duration of the first time, or near the second object position within a second duration of the second time. The processing system further includes a touch disambiguation module configured to determining whether the first object position and the second object position are associated with the same input object based on the first object position, the second object position, and the hover state.

A capacitive sensor device in accordance with one embodiment includes an input surface configured to interact with input objects in a sensing region, at least one sensing electrode configured to capacitively couple with the input objects in the sensing region, and a processing system communicatively coupled to the sensing electrode(s). The processing system is configured to obtain a set of sensor values using at least one sensing element of the input device, the set of sensor values including information indicative of a first input object position occurring at a first time, a second input object position occurring at a second time; and a hover state near the first input object position within a first duration of the first time, or near the second input object position within a second duration of the second time. The processing system is further configured to determine whether the first input object position and the second input object position are associated with the same input object based on the first object position, the second object position; and the hover state.

### BRIEF DESCRIPTION OF DRAWINGS

Various embodiments of the present invention will hereinafter be described in conjunction with the appended drawings, where like designations denote like elements, and:

FIG. 1 is a conceptual block diagram of an input device in accordance with one embodiment of the invention;

FIG. 2 is a top view of an input device depicting multiple input objects in accordance with an embodiment of the invention; and

FIGS. 3-8 are conceptual side view illustrations of various combinations of proximity events with non-contact signatures and contact signatures in accordance with embodiments of the present invention.

### DETAILED DESCRIPTION OF THE INVENTION

In general, and as set forth in greater detail below, the present invention relates to systems and methods for determining whether proximity events at different positions are produced by the same input object or by different input objects. One or more hover states (or proximity events with “non-contact” signatures) occurring near the two positions are used in making this determination.

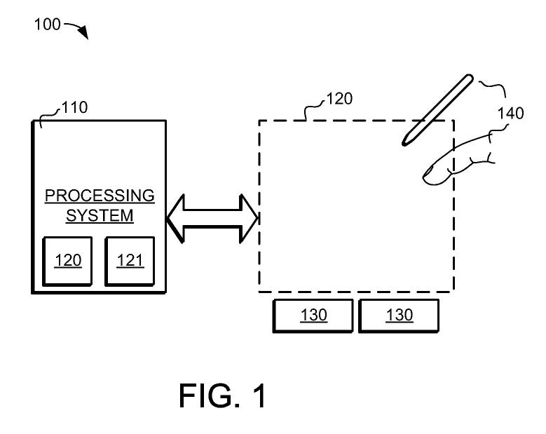

Turning now to the figures, FIG. 1 is a block diagram of an exemplary input device 100 in accordance with embodiments of the invention. The input device 100 may be configured to provide input to an electronic system (not shown). As used in this document, the term “electronic system” (or “electronic device”) broadly refers to any system capable of electronically processing information. Some non-limiting examples of electronic systems include personal computers of all sizes and shapes, such as desktop computers, laptop computers, netbook computers, tablets, web browsers, e-book readers, and personal digital assistants (PDAs). Additional example electronic systems include composite input devices, such as physical keyboards that include input device 100 and separate joysticks or key switches. Further example electronic systems include peripherals such as data input devices (including remote controls and mice), and data output devices (including display screens and printers). Other examples include remote terminals, kiosks, and video game machines (e.g., video game consoles, portable gaming devices, and the like). Other examples include communication devices (including cellular phones, such as smart phones), and media devices (including recorders, editors, and players such as televisions, set-top boxes, music players, digital photo frames, and digital cameras). Additionally, the electronic system could be a host or a slave to the input device.

The input device 100 can be implemented as a physical part of the electronic system, or can be physically separate from the electronic system. As appropriate, the input device 100 may communicate with parts of the electronic system using any one or more of the following: buses, networks, and other wired or wireless interconnections. Examples include I²C, SPI, PS/2, Universal Serial Bus (USB), Bluetooth, RF, and IRDA.

In FIG. 1, the input device 100 is shown as a proximity sensor device (also often referred to as a “touchpad” or a “touch sensor device”) configured to sense input provided by one or more input objects 140 in a sensing region 120. Example input objects include fingers and styli, as shown in FIG. 1.

Sensing region 120 encompasses any space above, around, in and/or near the input device 100 in which the input device 100 is able to detect user input (e.g., user input provided by one or more input objects 140). The sizes, shapes, and locations of particular sensing regions may vary widely from embodiment to embodiment. In some embodiments, the sensing region 120 extends from a surface of the input device 100 in one or more directions into space until signal-to-noise ratios prevent sufficiently accurate object detection. The distance to which this sensing region 120 extends in a particular direction, in various embodiments, may be on the order of less than a millimeter, millimeters, centimeters, or more, and may vary significantly with the type of sensing technology used and the accuracy desired. Thus, some embodiments sense input that comprises no contact with any surfaces of the input device 100, contact with an input surface (e.g. a touch surface) of the input device 100, contact with an input surface of the input device 100 coupled with some amount of applied force or pressure, and/or a combination thereof. In various embodiments, input surfaces may be provided by surfaces of casings within which the sensor electrodes reside, by face sheets applied over the sensor electrodes or any casings, etc. In some embodiments, the sensing region 120 has a rectangular shape when projected onto an input surface of the input device 100.

The input device 100 may utilize any combination of sensor components and sensing technologies to detect user input in the sensing region 120. The input device 100 comprises one or more sensing elements for detecting user input. As several non-limiting examples, the input device 100 may use capacitive, elastive, resistive, inductive, surface acoustic wave, and/or optical techniques.

Some implementations are configured to provide images that span one, two, three, or higher dimensional spaces. Some implementations are configured to provide projections of input along particular axes or planes.

In some resistive implementations of the input device 100, a flexible and conductive first layer is separated by one or more spacer elements from a conductive second layer. During operation, one or more voltage gradients are created across the layers. Pressing the flexible first layer may deflect it sufficiently to create electrical contact between the layers, resulting in voltage outputs reflective of the point(s) of contact between the layers. These voltage outputs may be used to determine positional information.

In some inductive implementations of the input device 100, one or more sensing elements pick up loop currents induced by a resonating coil or pair of coils. Some combination of the magnitude, phase, and frequency of the currents may then be used to determine positional information.

In some capacitive implementations of the input device 100, voltage or current is applied to create an electric field. Nearby input objects cause changes in the electric field, and produce detectable changes in capacitive coupling that may be detected as changes in voltage, current, or the like.

Some capacitive implementations utilize arrays or other regular or irregular patterns of capacitive sensing elements to create electric fields. In some capacitive implementations, separate sensing elements may be ohmically shorted together to form larger sensor electrodes. Some capacitive implementations utilize resistive sheets, which may be uniformly resistive.

Some capacitive implementations utilize “self capacitance” (or “absolute capacitance”) sensing methods based on changes in the capacitive coupling between sensor electrodes and an input object. In various embodiments, an input object near the sensor electrodes alters the electric field near the sensor electrodes, thus changing the measured capacitive coupling. In one implementation, an absolute capacitance sensing method operates by modulating sensor electrodes with respect to a reference voltage (e.g. system ground), and by detecting the capacitive coupling between the sensor electrodes and input objects.

Some capacitive implementations utilize “mutual capacitance” (or “transcapacitance”) sensing methods based on changes in the capacitive coupling between sensor electrodes. In various embodiments, an input object near the sensor electrodes alters the electric field between the sensor electrodes, thus changing the measured capacitive coupling. In one implementation, a transcapacitive sensing method operates by detecting the capacitive coupling between one or more transmitting electrodes and one or more receiving electrodes. Transmitting sensor electrodes may be modulated relative to a reference voltage (e.g., system ground) to facilitate transmission, and receiving sensor electrodes may be held substantially constant relative to the reference voltage to facilitate receipt. Sensor electrodes may be dedicated transmitters or receivers, or may be configured to both transmit and receive.

In FIG. 1, a processing system (or “processor”) 110 is shown as part of the input device 100. The processing system 110 is configured to operate the hardware of the input device 100 to detect input in the sensing region 120. The processing system 110 comprises parts of or all of one or more integrated circuits (ICs) and/or other circuitry components; in some embodiments, the processing system 110 also comprises electronically-readable instructions, such as firmware code, software code, and/or the like. In some embodiments, components composing the processing system 110 are located together, such as near sensing element(s) of the input device 100. In other embodiments, components of processing system 110 are physically separate with one or more components close to sensing element(s) of input device 100, and one or more components elsewhere. For example, the input device 100 may be a peripheral coupled to a desktop computer, and the processing system 110 may comprise software configured to run on a central processing unit of the desktop computer and one or more ICs (perhaps with associated firmware) separate from the central processing unit. As another example, the input device 100 may be physically integrated in a phone, and the processing system 110 may comprise circuits and firmware that are part of a main processor of the phone. In some embodiments, the processing system 110 is dedicated to implementing the input device 100. In other embodiments, the processing system 110 also performs other functions, such as operating display screens, driving haptic actuators, etc.

The processing system 110 may be implemented as a set of modules that handle different functions of the processing system 110. Each module may comprise circuitry that is a part of the processing system 110, firmware, software, or a combination thereof. In various embodiments, different combinations of modules may be used. Example modules include hardware operation modules for operating hardware such as sensor electrodes and display screens, data processing modules for processing data such as sensor signals and positional information, and reporting modules for reporting information. Further example modules include sensor operation modules configured to operate sensing element(s) to detect input, identification modules configured to identify gestures such as mode changing gestures, and mode changing modules for changing operation modes. In one embodiment, processing system 110 includes a sensing module 120 and a touch disambiguation module 121 as discussed in further detail below.

In some embodiments, the processing system 110 responds to user input (or lack of user input) in the sensing region 120 directly by causing one or more actions. Example actions include changing operation modes, as well as GUI actions such as cursor movement, selection, menu navigation, and other functions. In some embodiments, the processing system 110 provides information about the input (or lack of input) to some part of the electronic system (e.g. to a central processing system of the electronic system that is separate from the processing system 110, if such a separate central processing system exists). In some embodiments, some part of the electronic system processes information received from the processing system 110 to act on user input, such as to facilitate a full range of actions, including mode changing actions and GUI actions.

For example, in some embodiments, the processing system 110 operates the sensing element(s) of the input device 100 to produce electrical signals indicative of input (or lack of input) in the sensing region 120. The processing system 110 may perform any appropriate amount of processing on the electrical signals in producing the information provided to the electronic system. For example, the processing system 110 may digitize analog electrical signals obtained from the sensor electrodes. As another example, the processing system 110 may perform filtering or other signal conditioning. As yet another example, the processing system 110 may subtract or otherwise account for a baseline, such that the information reflects a difference between the electrical signals and the baseline. As yet further examples, the processing system 110 may determine positional information, recognize inputs as commands, recognize handwriting, and the like.

“Positional information” as used herein broadly encompasses absolute position, relative position, velocity, acceleration, and other types of spatial information. Exemplary “zero-dimensional” positional information includes near/far or contact/no contact information. Exemplary “one-dimensional” positional information includes positions along an axis. Exemplary “two-dimensional” positional information includes motions in a plane. Exemplary “three-dimensional” positional information includes instantaneous or average velocities in space. Further examples include other representations of spatial information. Historical data regarding one or more types of positional information may also be determined and/or stored, including, for example, historical data that tracks position, motion, or instantaneous velocity over time.

In some embodiments, the input device 100 is implemented with additional input components that are operated by the processing system 110 or by some other processing system. These additional input components may provide redundant functionality for input in the sensing region 120, or some other functionality. FIG. 1 shows buttons 130 near the sensing region 120 that can be used to facilitate selection of items using the input device 100. Other types of additional input components include sliders, balls, wheels, switches, and the like. Conversely, in some embodiments, the input device 100 may be implemented with no other input components.

In some embodiments, the input device 100 comprises a touch screen interface, and the sensing region 120 overlaps at least part of an active area of a display screen. For example, the input device 100 may comprise substantially transparent sensor electrodes overlaying the display screen and provide a touch screen interface for the associated electronic system. The display screen may be any type of dynamic display capable of displaying a visual interface to a user, and may include any type of light emitting diode (LED), organic LED (OLED), cathode ray tube (CRT), liquid crystal display (LCD), plasma, electroluminescence (EL), or other display technology. The input device 100 and the display screen may share physical elements. For example, some embodiments may utilize some of the same electrical components for displaying and sensing. As another example, the display screen may be operated in part or in total by the processing system 110.

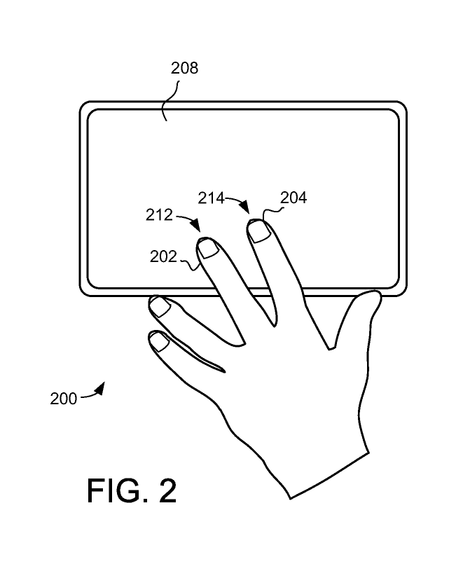

Turning now to FIG. 2, examples of input objects in a sensing region are illustrated. Specifically, FIG. 2 shows a top view of an exemplary input device 200. In the illustrated example, user finger 202 and user finger 204 provide input to the device 200. Fingers 202 and 204 are used in this example without loss of generality: other input objects, such as stylii or the like, may also be used. Input device 200 is configured to determine the respective positions of fingers 202 and 204 with respect to surface 208 using a sensor. For example, a capacitive proximity sensor, employing a plurality of sensor electrodes, may be configured to detect objects such as fingers 202 and 204 by detecting changes in transcapacitive coupling between sensor electrodes and to determine the position of the fingers from the detected changes in transcapacitive coupling.

In FIG. 2, finger 202 may produce a touch sensor event (or simply “proximity event”) at an object position (or simply “position”) 212, while finger 204 (a different input object) may produce a proximity event at position 214 at a different time or at substantially the same time. Alternatively, one of the two fingers 202 or 204 may produce a proximity event at position 202 as well as position 204 at different times (e.g., by sliding/moving quickly across the surface 208). In general, and as described in further detail below, systems and methods in accordance with the present invention are adapted to determine that the first proximity event and the second proximity event are caused by different input objects in response to detecting a third proximity event either (a) near the first position 212 within a first duration after the first time, or (b) near the second position 214 within a second duration before the second time, wherein the third proximity event has a non-contact signature.

The term “proximity event” as used herein generally comprehends a wide range of interactions between an input object and a sensing region. Two types of such interactions include, for example, a proximity event with a “non-contact” signature, and a proximity event with a “contact” signature. A proximity event with a contact signature will generally, but not exclusively, correspond to the case where a finger or other input object is contacting surface 208 (also referred to as a “landed state” or simply “landed”). Conversely, a proximity event with a non-contact signature will generally, but not exclusively, correspond to the case where a finger or other input object is not contacting surface 208 (also referred to as a “hover state”). Note, however, that these terms, while convenient in describing the present invention, do not require strict contact/non-contact as connoted by the terms themselves. For example, as is known in the art, a very light touch might fall within the definition of a non-contact signature (and be identified as such) even though there is, strictly speaking, actual contact between the input object and a surface.

In some embodiments, the distinction between contact and non-contact touch event signatures is determined using a peak signal (rather than an average signal) associated with a proximity event. In some embodiments, a non-contact signature is identified by determining that a signal has a value above some predetermined value (e.g., an ambient noise level or the like) but below a threshold value for a typical event having a contact signature. Furthermore, these predetermined threshold values may be dynamic and change automatically or manually during use. The term “signature” as used herein comprehends any type of qualitative and/or quantitative characterization of signals associated with proximity events, and is not limited to simple comparisons of peak signals.

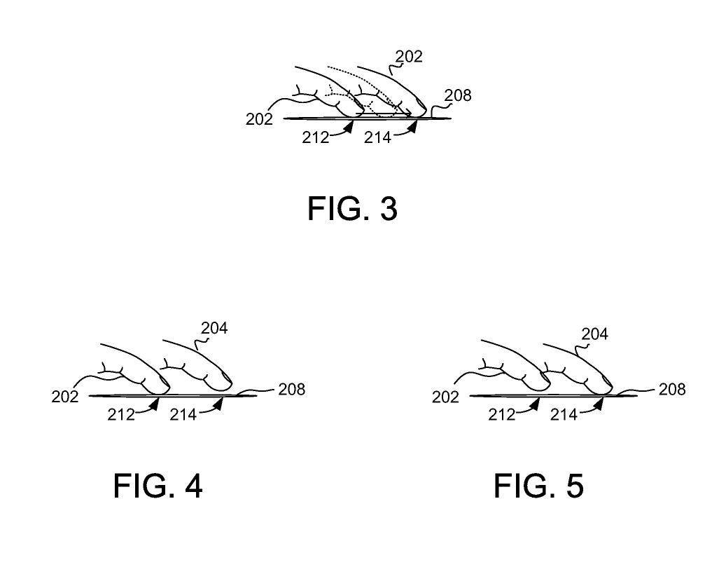

In accordance with the present invention, systems and methods are provided for determining whether proximity events with contact signatures at positions 212 and 214 are produced by the same input object, or by different input objects. To accomplish this, the system uses information indicative of one or more hover states (i.e., proximity events with a non-contact signature) occurring at position 212 and/or position 214 within certain time-frames as detailed below. In this regard, FIGS. 3-8 are conceptual side view illustrations of various ways in which an input object may interact with a sensing region, and are therefore useful in illustrating various embodiments of the present invention.

FIG. 3 depicts a common use case in which a single input object (finger 202) slides over surface 208 from position 212 to position 214. In this case, a proximity event with a contact signature will be identified at both positions 212 at 214 (generally at different times). If the finger slides substantially laterally (without a significant reduction in pressure, or being raised from the surface), no hover states will be identified near either position 212 or position 214.

FIGS. 4 and 5, in contrast, depict the case in which two different input objects (fingers 202 and 204) are associated with proximity events having contact signatures at two different positions: 212 and 214. That is, in FIG. 4, finger 202 is associated with a proximity event having a contact signature at position 212 at a first time. Similarly, in FIG. 5, finger 204 is associated with a proximity event having a contact signature at position 214 at a second time.

As shown in FIG. 4, finger 204 may be associated with a proximity event having a non-contact signature near position 214 at a time that is within a second duration before the second time. This is illustrated in FIG. 4 by finger 204 being drawn close to (but not actually contacting) surface 208. As discussed above, however, the invention is not so limited: in various embodiments it is possible for a “light touch” to be associated with a proximity event having a non-contact signature. Similarly, as shown in FIG. 5, finger 202 may be associated with a proximity event having a non-contact signature near position 212 at a time that is within a first duration after to the first time.

The first and second durations referenced above may be selected based on any number of factors, including, for example, the sampling rate at which proximity events are identified. That is, in some embodiments, the durations are less than or equal to two sampling periods. In other embodiments, the durations are based on a larger number of sampling periods (e.g., multiple sampling periods used for averaging or the like). The durations may be predetermined, user-configurable, or variable based on, for example, user behavior.

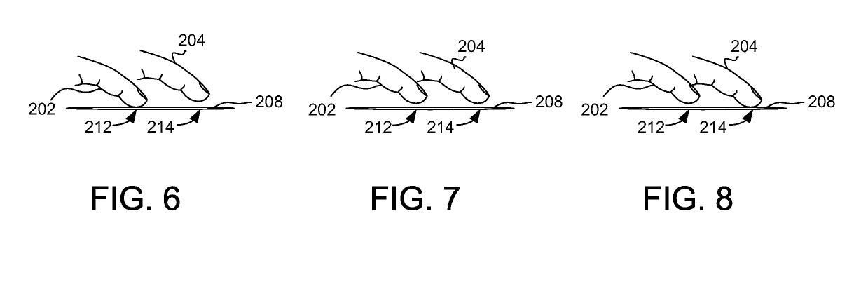

FIGS. 6-8 sequentially depict another case in which two hover states are detected. More particularly, in FIG. 6, finger 202 is associated with a proximity event having a contact signature at position 212 at a first time. In FIG. 8, finger 204 is associated with a proximity event having a contact signature at position 214 at a second time. In between, as illustrated in FIG. 7, both fingers 202 and 204 are associated with respective non-contact proximity events at positions 212 and 214 within one or more durations relative to the first and second times. That is, FIGS. 6-8 together illustrate the case where two hover events (not just one), can be used for determining that the proximity events at positions 212 and 214 were produced by different objects.

In order to determine whether one proximity event and a second proximity event are caused by the same input object (i.e., two proximity events with respective contact signatures), the present system (e.g., sensing module 120 and disambiguation module 121 shown in FIG. 1) identifies a third proximity event having a non-contact signature. The third proximity event is identified at approximately the first position within a first duration after the first time, and/or at approximately the second position within a second duration before the second time. The third proximity event is then used along with information regarding the first and second positions to determine whether the same or different input objects were used. That is, the system determines that the first proximity event and the second proximity event are caused by different input objects if it detects a third proximity event either (a) near the first position within a first duration after the first time, or (b) near the second position within a second duration before the second time. When a second hover state is detected, the system may further determine that the first proximity event and the second proximity event are not caused by the same input object if the second hover state is detected near the second object position 214 within the first duration after the first time, or the second hover state is detected near the first object position 212 within the second duration before the second time. The system may then report this result in any appropriate manner—e.g., by reporting a lateral motion control signal if the first object position and the second object position are caused by the same input object.

It should be understood that while many embodiments of the invention are described in the context of a fully functioning apparatus, the mechanisms of the present invention are capable of being distributed as a program product (e.g., software) in a variety of forms. For example, the mechanisms of the present invention may be implemented and distributed as a software program on information bearing media that are readable by electronic processors (e.g., non-transitory computer-readable and/or recordable/writable information bearing media readable by the processing system 110). Additionally, the embodiments of the present invention apply equally regardless of the particular type of medium used to carry out the distribution. Examples of non-transitory, electronically readable media include various discs, memory sticks, memory cards, memory modules, and the like. Electronically readable media may be based on flash, optical, magnetic, holographic, or any other storage technology.

Thus, the embodiments and examples set forth herein were presented in order to best explain the present invention and its particular application and to thereby enable those skilled in the art to make and use the invention. However, those skilled in the art will recognize that the foregoing description and examples have been presented for the purposes of illustration and example only. The description as set forth is not intended to be exhaustive or to limit the invention to the precise form disclosed.

What is claimed is:

1. A method for operating a touch sensor device comprising:
detecting a first proximity event at a first position at a first time, the first proximity event having a contact signature;
detecting a second proximity event at a second position at a second time, the second proximity event having a contact signature; and
determining that the first proximity event and the second proximity event are caused by different input objects in response to detecting a third proximity event either (a) near the first position within a first duration after the first time, or (b) near the second position within a second duration before the second time, wherein the third proximity event has a non-contact signature.

2. The method of claim 1, further including:
detecting a fourth proximity event, wherein the fourth proximity even has a non-contact signature; and
determining that the first proximity event and the second proximity event are not caused by the same input object if:
the fourth proximity event is detected near the second position within the first duration after the first time, or
the fourth proximity event is detected near the first position within the second duration before the second time.

3. The method of claim 1, further comprising reporting a lateral motion control signal if the first object position and the second object position are caused by the same input object.

4. The method of claim 1, wherein the first duration and the second duration each has a length equal to less than two proximity event sampling periods.

5. The method of claim 1, wherein the third proximity event corresponds to a peak signal that is less than a predetermined value.

6. The method of claim 1, further comprising:
determining that the first proximity event and the second proximity event are caused by different input objects; and
not reporting a lateral motion control signal.

7. A processing system for an input device, the processing system comprising:
a sensing module configured to acquire a set of sensor values using at least one sensing element of the input device, the set of sensor values including information indicative of:
a first object position occurring at a first time;
a second object position occurring at a second time; and
a hover state; and
a touch disambiguation module configured to determine that the first object position and the second object position are associated with different input objects when the hover state is detected near the first object position within a first duration after the first time, or the hover state is detected near the second object position within a second duration before the second time.

8. The processing system of claim 7, wherein the set of sensor values includes information indicative of a second hover state, and wherein the touch disambiguation module is further configured to determine that the first object position and the second object position are associated with different input objects if:
the second hover state is detected near the second object position within the first duration after the first time, or
the second hover state is detected near the first object position within the second duration before the second time.

9. The processing system of claim 7, wherein the processing system is configured to report a lateral motion control signal if the first object position and the second object position are caused by the same input object.

10. The processing system of claim 7, wherein the processing system is configured to not report a lateral motion control signal if the first object position and the second object position are not caused by the same input object.

11. The processing system of claim 7, wherein the sensing module acquires the set of sensor values during a sample period, wherein the first duration and the second duration are each equal to or less than two of the sample periods.

12. The processing system of claim 8, wherein the information indicative of the hover state includes a peak signal less than a predetermined threshold.

13. A capacitive sensor device comprising:
an input surface configured to interact with input objects in a sensing region;
at least one sensing electrode configured to capacitively couple with the input objects in the sensing region;
a processing system communicatively coupled to the at least one sensing electrode, the processing system configured to:
obtain a set of sensor values using the at least one sensing electrode of the input device, the set of sensor values including information indicative of a first input object position occurring at a first time, a second input object position occurring at a second time; and a hover state near the first input object position within a first duration of the first time, or near the second input object position within a second duration of the second time; and
determine that the first input object position and the second input object position are not associated with the same input object if (a) the hover state is detected near the first object position within the first duration after the first time; or (b) the hover state is detected near the second object position within the second duration before the second time.

14. The capacitive sensor device of claim 13, wherein the processing system is configured to obtain a sensor value indicative of a second hover state, and determine that the first input object position and the second input object position are not associated with the same input object if (a) the second hover state is detected near the second object position within the first duration after the first time; or (b) the second hover state is detected near the first object position within the second duration before the second time.

15. The capacitive sensor device of claim 13, wherein the processing system is configured to report a lateral motion control signal if the first object position and the second object position are caused by the same input object.

16. The capacitive sensor device of claim 13, wherein the processing system is configured to not report a lateral motion control signal if the first object position and the second object position are not caused by the same input object.

17. The capacitive sensor device of claim 13, wherein the set of sensor values are acquired at a rate having a sampling period, and wherein the first duration and the second duration each has a length equal to less than two of the sampling periods.

18. The capacitive sensor device of claim 13, wherein information indicative of a hover state includes a peak signal less than a predetermined threshold.

19. The capacitive sensor device of claim 13, wherein the first duration and the second duration are variable and based on user behavior.
